(19) United States
(12) Patent Application Publication
(10) Pub. No.: US 2026/0163448 A1
(43) Pub. Date: Jun. 11, 2026

(54) ELECTRIC WATER PUMP

(71) Applicant: HYUNDAI WIA Corporation, Changwon-si (KR)

(72) Inventors: Keon Sik LEE, Uiwang-si (KR); Chul Bae JEON, Uiwang-si (KR); Ji Sub SHIN, Uiwang-si (KR); Nam Hoon KIM, Uiwang-si (KR); Young Ho KIM, Uiwang-si (KR)

(73) Assignee: HYUNDAI WIA Corporation, Changwon-si (KR)

(21) Appl. No.: 19/400,622

(22) Filed: Nov. 25, 2025

(30) Foreign Application Priority Data
Dec. 11, 2024 (KR) 10-2024-0183261

(51) Int. Cl. H02K 7/14; F04D 13/06; F04D 29/18; F04D 29/40; H02K 1/12; H02K 5/20; H05K 7/14

(52) U.S. Cl. CPC H02K 7/14; F04D 13/06; F04D 29/18; F04D 29/406; H02K 1/12; H02K 5/20; H05K 7/1432

(57) ABSTRACT

Disclosed is an electric water pump. The electric water pump includes a housing including a housing body, a printed circuit board (PCB), and a stator back yoke, and an impeller including an impeller body and a magnet. The housing body includes an inlet and an outlet and has an internal space defined therein, and the stator back yoke is integrally embedded in the housing body. The impeller is disposed in the internal space in the housing body and is mounted to be rotatable about a rotation shaft.

### CROSS-REFERENCE TO THE RELATED APPLICATION

The present application claims priority to and the benefit of Korean Patent Application No. 10-2024-0183261, filed on Dec. 11, 2024, in the Korean Intellectual Property Office, the entire disclosure of which is incorporated herein by reference.

### BACKGROUND

### 1. Field

The present disclosure relates to an electric water pump, and more particularly, to an electric water pump of an axial flux motor type that may be used, for example, to supply coolant in a vehicle.

### 2. Description of the Related Art

An electric water pump is used to supply coolant for the purpose of cooling a battery, a powertrain electronics (PE) compartment, or the like in a vehicle. For example, an electric water pump of an axial flux motor type may be used. However, a conventional electric water pump has a problem in that components such as a printed circuit board (PCB), a back yoke, and a magnet are in contact with the coolant and are easily corroded by chemical components of the coolant. Foreign substances generated by such corrosion may cause malfunction of the pump and reduce the durability of the pump. Furthermore, if the PCB, the back yoke, and the magnet are not tightly fixed, the rigidity of the components may decrease, and resonance caused by vibration may deteriorate noise, vibration and harshness (NVH) performance.

### SUMMARY

An aspect of the present disclosure is to provide an electric water pump capable of preventing corrosion caused by contact with coolant.

Another aspect of the present disclosure is to provide an electric water pump capable of tightly fixing related components.

An electric water pump according to the present disclosure includes a housing including a housing body, a printed circuit board (PCB), and a stator back yoke, the housing body including an inlet and an outlet and having an internal space defined therein, the stator back yoke being integrally embedded in the housing body, and an impeller disposed in the internal space in the housing body and mounted to be rotatable about a rotation shaft, the impeller including an impeller body and a magnet.

The PCB may be integrally embedded in the housing body together with the stator back yoke.

The PCB may be structured such that a copper foil pattern, serving as a stator coil, is printed on a substrate to be integrally formed with the substrate.

The magnet may be integrally embedded in the impeller body.

The PCB and the magnet may be disposed on one surface of the housing and one surface of the impeller, respectively, facing each other in a direction parallel to the rotation shaft, and the stator back yoke may be disposed opposite the magnet with respect to the PCB.

The PCB may be integrally embedded in the housing body together with the stator back yoke.

A gap may be defined between one surface of the housing and one surface of the impeller to allow coolant to pass between one surface of the housing and one surface of the impeller.

The PCB may be disposed outside the housing body on a side of one surface of the housing.

A gap may be defined between the PCB and one surface of the impeller to allow coolant to pass between the PCB and one surface of the impeller.

The impeller body may include a rotation-shaft support portion surrounding the rotation shaft, and the PCB may be formed in a ring shape to allow the rotation-shaft support portion to be located at the center of the PCB.

A gap may be defined between the PCB and the rotation-shaft support portion to allow coolant to pass between the PCB and the rotation-shaft support portion.

A gap may be defined between the PCB and the housing body to allow coolant to pass between the PCB and the housing body on a side of one surface of the housing.

The PCB may include a through-hole formed therein to allow coolant to pass through the PCB.

The housing may further include a sealing member disposed between an edge portion of the PCB and the housing body.

The impeller may further include a rotor back yoke.

The rotor back yoke may be integrally embedded in the impeller body.

The magnet and the rotor back yoke may be integrally embedded in the impeller body.

The PCB and the magnet may be disposed on one surface of the housing and one surface of the impeller, respectively, facing each other in a direction parallel to the rotation shaft, the stator back yoke may be disposed opposite the magnet with respect to the PCB, and the rotor back yoke may be disposed opposite the PCB with respect to the magnet.

The impeller body may include a rotation-shaft support portion surrounding the rotation shaft, and the magnet may be formed in a ring shape to allow the rotation-shaft support portion to be located at the center of the magnet.

The impeller body may include a rotation-shaft support portion surrounding the rotation shaft, and the electric water pump may include a bearing disposed between the rotation-shaft support portion and the rotation shaft.

### BRIEF DESCRIPTION OF THE DRAWINGS

The accompanying drawings, which are incorporated in this specification, illustrate exemplary embodiments and serve to further illustrate the technical ideas of the disclosure in conjunction with the detailed description of exemplary embodiments that follows, and the disclosure is not to be construed as limited to what is shown in such drawings. In the drawings:

FIG. 1 is a cross-sectional view of an electric water pump according to a first embodiment of the present disclosure;

FIG. 2 is an enlarged view of portion A in FIG. 1;

FIG. 3 is a view showing a flow of coolant in FIG. 2;

FIG. 4 is a plan view of a printed circuit board (PCB) of the electric water pump according to the first embodiment of the present disclosure;

FIG. 5 is a partial cross-sectional view of an electric water pump according to a second embodiment of the present disclosure, which shows a portion corresponding to FIG. 2;

FIG. 6 is a partial cross-sectional view of an electric water pump according to a third embodiment of the present disclosure, which shows a portion corresponding to FIG. 2;

FIG. 7 is a view showing a flow of coolant in FIG. 6;

FIG. 8 is a partial cross-sectional view of an electric water pump according to a fourth embodiment of the present disclosure, which shows a portion corresponding to FIG. 2;

FIG. 9 is a view showing a flow of coolant in FIG. 8;

FIG. 10 is a partial cross-sectional view of an electric water pump according to a fifth embodiment of the present disclosure, which shows a portion corresponding to FIG. 2; and

FIG. 11 is a view showing a flow of coolant in FIG. 10.

### DETAILED DESCRIPTION OF EXEMPLARY EMBODIMENTS

Electric water pumps according to embodiments of the present disclosure will be described in detail with reference to the accompanying drawings.

### First Embodiment

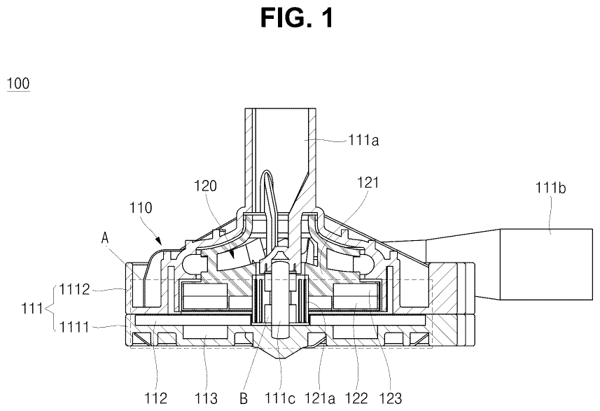

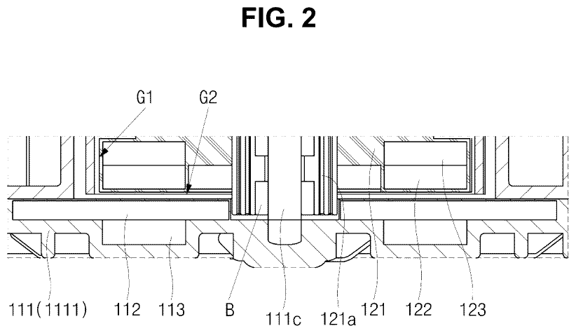

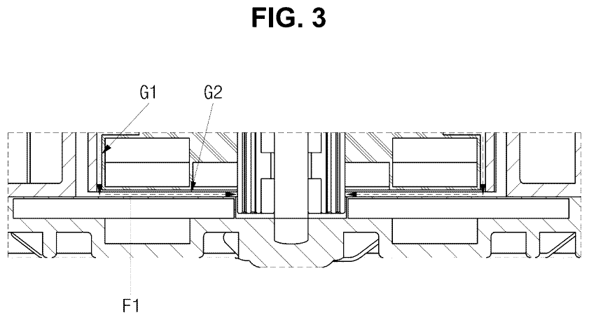

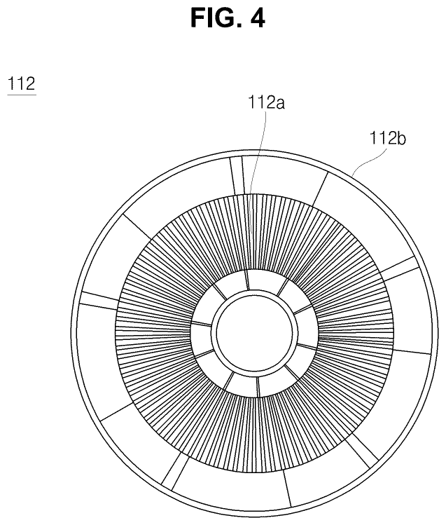

FIG. 1 is a cross-sectional view of an electric water pump 100 according to a first embodiment of the present disclosure. FIG. 2 is an enlarged view of portion A in FIG. 1. FIG. 3 is a view showing a flow of coolant F1 in FIG. 2. FIG. 4 is a plan view of a printed circuit board (PCB) 112 of the electric water pump 100 according to the first embodiment of the present disclosure.

Referring to FIGS. 1 to 4, the electric water pump 100 according to the first embodiment of the present disclosure may be configured, for example, as an axial flux motor (AFM) type. The electric water pump 100 may include a housing 110 and an impeller 120.

The housing 110 may include a housing body 111, a PCB 112, and a stator back yoke 113.

The housing body 111 may include an inlet 111a through which a fluid, for example, coolant, is introduced and an outlet 111b through which the coolant is discharged. In the drawings, the inlet 111a is illustrated as being formed vertically, and the outlet 111b is illustrated as being formed horizontally.

The housing body 111 may have an internal space defined therein to accommodate the impeller 120. The housing body 111 may include a rotation shaft 111c to rotate the impeller 120.

The housing body 111 may be divided into a plurality of parts. For example, the housing body 111 may be divided into a lower part 1111 and an upper part 1112. The electric water pump 100 may be assembled in a manner such that the impeller 120 is mounted on the lower part 1111 and the upper part 1112 is coupled to the lower part 1111 and the impeller 120 from above. In the drawings, the inlet 111a and the outlet 111b are illustrated as being formed in the upper part 1112, and the rotation shaft 111c is illustrated as extending upward from the lower part 1111.

The PCB 112 may include elements for driving and control of the motor. The PCB 112 may be disposed on one side of the housing body 111 that faces a magnet 122 of the impeller 120. Based on the drawings, the PCB 112 may be disposed on the upper surface of the lower part 1111 of the housing body 111.

For example, the PCB 112 may be formed in a ring shape or an annular shape, and the rotation shaft 111c or a rotation-shaft support portion 121a of an impeller body 121 of the impeller 120 may be concentrically positioned at the center of the PCB 112.

As shown in FIG. 4, the PCB 112 may have a structure in which a copper foil pattern 112a, serving as a stator coil, is printed on a disc-shaped substrate 112b to be integrally formed therewith. Therefore, compared to a conventional structure in which a copper wire is wound around an iron core, a more compact structure may be achieved. The PCB 112 may include elements (not shown) for motor driving control. The types or arrangement of such elements may be appropriately modified as needed, and thus are not specifically limited in the present disclosure.

The stator back yoke 113 may serve to define a magnetic flux path together with a rotor back yoke 123 of the impeller 120. The stator back yoke 113 may be disposed opposite the rotor back yoke 123 with respect to the PCB 112. Based on the drawings, the stator back yoke 113 may be disposed below the PCB 112.

As shown in FIG. 2, the PCB 112 and the stator back yoke 113 of the electric water pump 100 according to the first embodiment of the present disclosure may be integrally embedded in the housing body 111. The material forming the housing body 111 may entirely surround the PCB 112 and the stator back yoke 113. For example, the PCB 112 and the stator back yoke 113 may be integrally fabricated with the housing body 111 through an over-molding or insert-molding process. Therefore, no separate means are required to prevent corrosion of the PCB 112 and the stator back yoke 113 due to contact with coolant, and no separate means are required to fix the PCB 112 and the stator back yoke 113 to the housing body 111.

The impeller 120 may be disposed in the internal space in the housing body 111 and may be mounted so as to be rotatable about the rotation shaft 111c. The impeller 120 may include an impeller body 121, a magnet 122, and a rotor back yoke 123. The impeller body 121 may be configured to force a fluid to flow from the inlet 111a to the outlet 111b as the impeller body 121 rotates about the rotation shaft 111c.

The impeller body 121 may include a rotation-shaft support portion 121a surrounding the rotation shaft 111c, and a bearing B may be disposed between the rotation shaft 111c and the rotation-shaft support portion 121a. The magnet 122 may be disposed on one surface of the impeller body 121 that faces the PCB 112. Based on the drawings, the magnet 122 may be disposed on the lower surface of the impeller body 121. For example, the magnet 122 may be formed in a ring shape or an annular shape, and the rotation-shaft support portion 121a of the impeller body 121 may be concentrically positioned at the center of the magnet 122. The magnet 122 may be formed to be relatively flat. For example, a length of the magnet 122 in a rotation-shaft direction may be less than a length between an outer-diameter portion and an inner-diameter portion of the magnet 122. With this structure, the electric water pump 100 may be designed more compactly.

The rotor back yoke 123 may serve to form a magnetic flux path together with the stator back yoke 113. The rotor back yoke 123 may be disposed opposite the stator back yoke 113 with respect to the magnet 122. Based on the drawings, the rotor back yoke 123 may be disposed on the magnet 122.

The magnet 122 and the rotor back yoke 123 may be integrally embedded in the impeller body 121. The material forming the impeller body 121 may entirely surround the magnet 122 and the rotor back yoke 123. For example, the magnet 122 and the rotor back yoke 123 may be integrally fabricated with the impeller body 121 through an over-molding or insert-molding process.

Therefore, no separate means are required to prevent corrosion of the magnet 122 and the rotor back yoke 123 due to contact with coolant, and no separate means are required to fix the magnet 122 and the rotor back yoke 123 to the impeller body 121.

In order to allow the impeller 120 to smoothly rotate relative to the housing 110, predetermined gaps (clearances or spacing) G1 and G2 may be defined between the housing 110 and the impeller 120. For example, a gap G1 may be defined between the inner circumferential surface of the internal space in the housing body 111 and the outer circumferential surface of the impeller body 121, and a gap G2 may be defined between the upper surface of the lower part 1111 of the housing body 111 and the lower surface of the impeller body 121. As shown in FIG. 3, the gaps G1 and G2 may also serve to allow coolant F1 flowing from the inlet 111a toward the outlet 111b to naturally enter and pass through the gaps G1 and G2. As a result, the PCB 112 and the magnet 122 may be cooled by the coolant F1.

### Second Embodiment

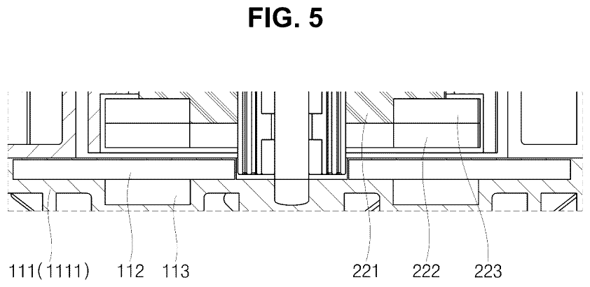

FIG. 5 is a partial cross-sectional view of an electric water pump according to a second embodiment of the present disclosure, which shows a portion corresponding to FIG. 2.

In the electric water pump 100 according to the first embodiment of the present disclosure, the PCB 112 and the stator back yoke 113 provided in the housing 110 are integrally fabricated with the housing body 111 through an over-molding or insert-molding process so as to be integrally embedded in the housing body 111, and the magnet 122 and the rotor back yoke 123 provided in the impeller 120 are integrally fabricated with the impeller body 121 through an over-molding or insert-molding process so as to be integrally embedded in the impeller body 121, whereas the electric water pump according to the second embodiment of the present disclosure is distinguished in that the PCB 112 and the stator back yoke 113 provided in the housing are integrally fabricated with the housing body 111 through an over-molding or insert-molding process so as to be integrally embedded in the housing body 111, but the impeller is configured differently from the impeller of the electric water pump according to the first embodiment of the present disclosure. In the electric water pump according to the second embodiment of the present disclosure, the other parts are substantially the same as those of the electric water pump according to the first embodiment of the present disclosure. Even if some differences exist, such differences are merely modifications that a person of ordinary skill in the art may readily make based on the configurations described above and to be described below. Thus, redundant descriptions of the same parts will be omitted, and the same reference numerals are used throughout the detailed description of the disclosure and the drawings.

For example, the magnet 222 may be formed of neodymium, or the rotor back yoke 223 may be formed of a material such as SUM24L. As such, if the magnet 222 or the rotor back yoke 223 is formed of a material exhibiting high corrosion resistance to the coolant, the magnet 222 or the rotor back yoke 223 may not need to be embedded in the impeller body 221.

To this end, in the electric water pump according to the second embodiment of the present disclosure, the PCB 112 and the stator back yoke 113 provided in the housing may be integrally fabricated with the housing body 111 through an over-molding or insert-molding process so as to be integrally embedded in the housing body 111, whereas the magnet 222 or the rotor back yoke 223 provided in the impeller may be fixed outside the lower surface of the impeller body 221 using, for example, a dedicated bracket or other fastening means, rather than being integrally embedded in the impeller body 221.

Furthermore, in order to more securely protect the magnet 222 or the rotor back yoke 223 from corrosion caused by contact with the coolant, a coating process may be performed on at least the surface of the magnet 222 or the rotor back yoke 223 that is exposed to the coolant. The material or method of the coating process is not specifically limited in the present disclosure, as long as the same is capable of appropriately protecting the magnet 222 or the rotor back yoke 223 from corrosion caused by contact with the coolant without adversely affecting the electromagnetic driving of the magnet 222 or the rotor back yoke 223.

### Third Embodiment

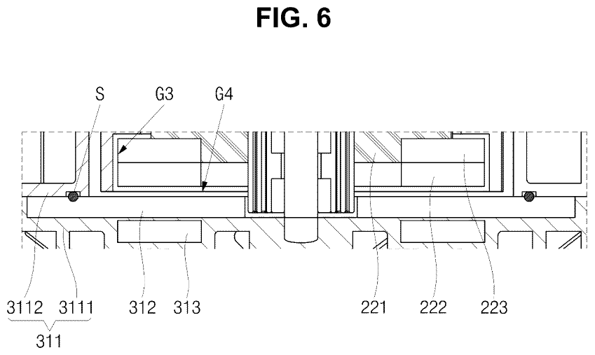

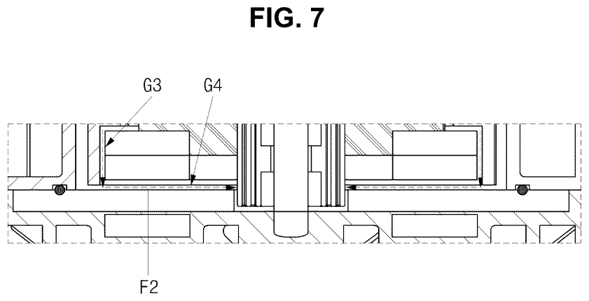

FIG. 6 is a partial cross-sectional view of an electric water pump according to a third embodiment of the present disclosure, which shows a portion corresponding to FIG. 2. FIG. 7 is a view showing a flow of coolant F2 in FIG. 6.

In the electric water pump 100 according to the first embodiment of the present disclosure or the electric water pump according to the second embodiment of the present disclosure, the PCB 112 and the stator back yoke 113 provided in the housing 110 are integrally fabricated with the housing body 111 through an over-molding or insert-molding process so as to be integrally embedded in the housing body 111, whereas the electric water pump according to the third embodiment of the present disclosure is distinguished in that only the stator back yoke 313 is integrally fabricated with the housing body 311 through an over-molding or insert-molding process so as to be integrally embedded in the housing body 311, but the PCB 312 is mounted differently from the PCB of the electric water pump according to the first embodiment of the present disclosure or the PCB of the electric water pump according to the second embodiment of the present disclosure. In the electric water pump according to the third embodiment of the present disclosure, the other parts are substantially the same as those of the electric water pump according to the first embodiment of the present disclosure or the electric water pump according to the second embodiment of the present disclosure. Even if some differences exist, such differences are merely modifications that a person of ordinary skill in the art may readily make based on the configurations described above and to be described below. Thus, redundant descriptions of the same parts will be omitted, and the same reference numerals are used throughout the detailed description of the disclosure and the drawings.

For example, the PCB 312 may be formed of a material such as FR4. As such, if the PCB 312 is formed of a material exhibiting high corrosion resistance to the coolant, the PCB 312 may not need to be embedded in the housing body 311.

To this end, in the electric water pump according to the third embodiment of the present disclosure, only the stator back yoke 313 may be integrally fabricated with the housing body 311 through an over-molding or insert-molding process so as to be integrally embedded in the housing body 311, whereas the PCB 312 may be fixed outside the upper surface of the lower part 3111 of the housing body 311 using, for example, a dedicated bracket or other fastening means, rather than being integrally embedded in the housing body 311.

Furthermore, in order to more securely protect the PCB 312 from corrosion caused by contact with the coolant, a coating process may be performed on at least the surface of the PCB 312 that is exposed to the coolant. The material or method of the coating process is not specifically limited in the present disclosure, as long as the same is capable of appropriately protecting the PCB 312 from corrosion caused by contact with the coolant without adversely affecting the electromagnetic driving of the PCB 312.

As described above, in order to allow the impeller to smoothly rotate relative to the housing, the predetermined gaps (clearances or spacing) G3 and G4 may be defined between the housing and the impeller. As a result, as shown in FIG. 6, a gap G4 may be defined between the PCB 312 and the lower surface of the impeller to allow the coolant F2 to pass therebetween. This may allow the coolant F2 to directly contact the PCB 312, thereby enabling effective cooling of the PCB 312.

A sealing member S may be provided to prevent the coolant F2 from leaking out of the housing body 311. For example, the upper surface of an edge portion of the PCB 312 may be in contact with the lower surface of the upper part 3112 of the housing body 311, and the sealing member S may be disposed therebetween. The sealing member S may include an O-ring, and a circular groove may be formed in the lower surface of the upper part 3112 of the housing body 311 to receive the O-ring-type sealing member S.

Similar to the electric water pump 100 according to the first embodiment of the present disclosure, in the electric water pump according to the third embodiment of the present disclosure, the magnet 122 and the rotor back yoke 123 may be integrally fabricated with the impeller body 121 through an over-molding or insert-molding process so as to be integrally embedded in the impeller body 121. Similar to the electric water pump according to the second embodiment of the present disclosure, the magnet 222 and the rotor back yoke 223 may be fixed outside the lower surface of the impeller body 221. The latter case is illustrated in the drawings.

### Fourth Embodiment

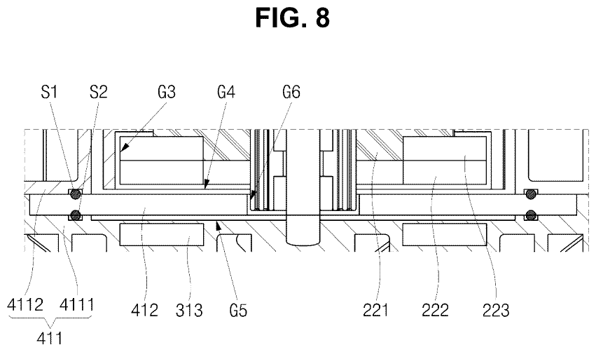

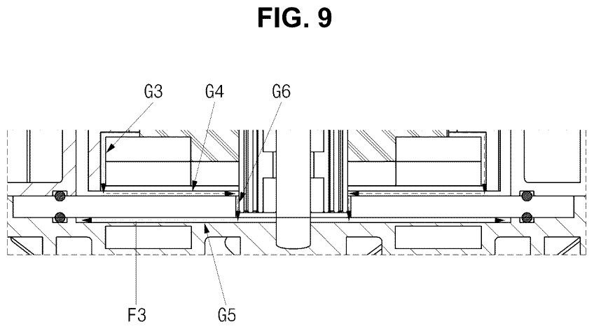

FIG. 8 is a partial cross-sectional view of an electric water pump according to a fourth embodiment of the present disclosure, which shows a portion corresponding to FIG. 2. FIG. 9 is a view showing a flow of coolant F3 in FIG. 8.

The electric water pump according to the fourth embodiment of the present disclosure may be a partial modification of the electric water pump according to the third embodiment of the present disclosure. In the electric water pump according to the third embodiment of the present disclosure, an entire area of the PCB 312 may be in contact with the upper surface of the lower part 3111 of the housing body 311, whereas the electric water pump according to the fourth embodiment of the present disclosure is distinguished in that at least a portion of the PCB 412 is spaced apart from the upper surface of the lower part 4111 of the housing body 411.

Furthermore, the electric water pump according to the fourth embodiment of the present disclosure may include a gap G5 defined between the PCB 412 and the upper surface of the lower part 4111 of the housing body 411 to allow the coolant to pass therebetween.

For example, the gap G5 may be formed by recessing the upper surface of the lower part 4111 of the housing body 411 to have a step.

As shown in FIG. 9, the coolant F3 may flow from the gap G3 between the inner circumferential surface of the internal space in the housing body 411 and the outer circumferential surface of the impeller to the gap G5 between the PCB 412 and the upper surface of the lower part 4111 of the housing body 411 via the gap G4 between the PCB 412 and the lower surface of the impeller and the gap G6 between the PCB 412 and the rotation-shaft support portion of the impeller body 221. As a result, both the upper side and the lower side of the PCB 412 may be cooled by the coolant F3, thereby achieving more effective cooling of the PCB 412.

Sealing members S1 and S2 may be provided to prevent the coolant F3 from leaking out of the housing body 411. For example, the upper surface of an edge portion of the PCB 412 may be in contact with the lower surface of the upper part 4112 of the housing body 411, and the sealing member S1 may be disposed therebetween. The sealing member S1 may include an O-ring, and a circular groove may be formed in the lower surface of the upper part 4112 of the housing body 411 to receive the O-ring-type sealing member S1. Similarly, the lower surface of the edge portion of the PCB 412 may be in contact with the upper surface of the lower part 4111 of the housing body 411, and the sealing member S2 may be disposed therebetween. The sealing member S2 may include an O-ring, and a circular groove may be formed in the upper surface of the lower part 4111 of the housing body 411 to receive the O-ring-type sealing member S2.

In the electric water pump according to the fourth embodiment of the present disclosure, the other parts are substantially the same as those of the electric water pump according to the third embodiment of the present disclosure. Even if some differences exist, such differences are merely modifications that a person of ordinary skill in the art may readily make based on the configurations described above. Thus, redundant descriptions of the same parts will be omitted, and the same reference numerals are used throughout the detailed description of the disclosure and the drawings.

### Fifth Embodiment

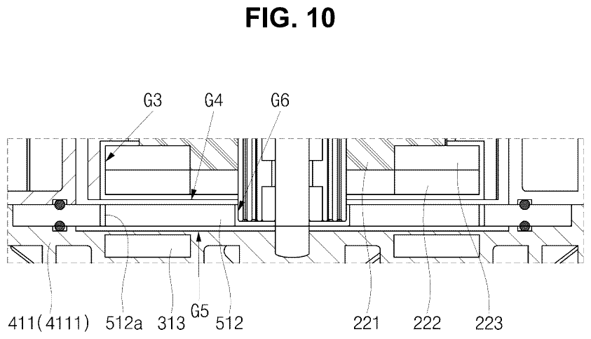

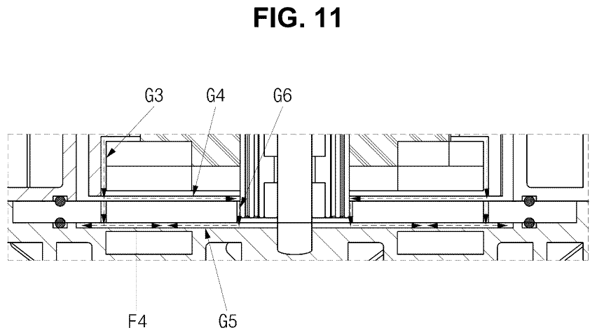

FIG. 10 is a partial cross-sectional view of an electric water pump according to a fifth embodiment of the present disclosure, which shows a portion corresponding to FIG. 2. FIG. 11 is a view showing a flow of coolant F4 in FIG. 10.

The electric water pump according to the fifth embodiment of the present disclosure differs from the electric water pump according to the fourth embodiment of the present disclosure in that the PCB 512 includes a through-hole 512a formed therein.

For example, the electric water pump according to the fifth embodiment of the present disclosure may include a through-hole 512a formed vertically through the PCB 512.

As shown in FIG. 10, in addition to allowing the coolant F4 to flow from the gap G3 between the inner circumferential surface of the internal space in the housing body 411 and the outer circumferential surface of the impeller to the gap G5 between the PCB 512 and the upper surface of the lower part 4111 of the housing body 411 via the gap G4 between the PCB 512 and the lower surface of the impeller and the gap G6 between the PCB 512 and the rotation-shaft support portion of the impeller body 221, the coolant F4 may be allowed to directly flow from the gap G3 between the inner circumferential surface of the internal space in the housing body 411 and the outer circumferential surface of the impeller to the gap G5 between the PCB 512 and the upper surface of the lower part 4111 of the housing body 411 through the through-hole 512a, thereby enhancing the cooling effect.

The through-hole 512a may be disposed in alignment with the gap G3 between the inner circumferential surface of the internal space in the housing body 411 and the outer circumferential surface of the impeller in a direction parallel to the rotation shaft. This may allow the coolant escaping from the gap G3 between the inner circumferential surface of the internal space in the housing body 411 and the outer circumferential surface of the impeller to more smoothly enter the through-hole 512a.

In some embodiments, the through-hole 512a may be provided in plural, and the plurality of through-holes 512a may be arranged in the circumferential direction or radial direction of the PCB 512 or may be distributed over the entire area of the PCB 512.

In the electric water pump according to the fifth embodiment of the present disclosure, the other parts are substantially the same as those of the electric water pump according to the fourth embodiment of the present disclosure. Even if some differences exist, such differences are merely modifications that a person of ordinary skill in the art may readily make based on the configurations described above. Thus, redundant descriptions of the same parts will be omitted, and the same reference numerals are used throughout the detailed description of the disclosure and the drawings.

The electric water pump described above is merely one of various embodiments of the electric water pump according to the present disclosure.

As is apparent from the above description, in the electric water pump according to the present disclosure, components susceptible to corrosion due to contact with coolant, such as a stator back yoke, a PCB, a magnet, and a rotor back yoke, may be integrally fabricated with a housing body or an impeller body through an over-molding or insert-molding process so as to be integrally embedded in the housing body or the impeller body, thereby preventing corrosion caused by contact with the coolant.

Furthermore, the related components may be securely fixed through the over-molding or insert-molding process.

Furthermore, gaps or passages may be defined between the related components to allow coolant to pass therebetween, thereby achieving a cooling effect using the coolant.

Although the present disclosure has been described above with reference to the exemplary embodiments, the present disclosure is not limited thereto, and it should be understood that various changes and modifications can be made by those skilled in the art without departing from the spirit and scope of the disclosure as defined by the appended claims.

What is claimed is:

1. An electric water pump comprising:
a housing comprising a housing body, a printed circuit board (PCB), and a stator back yoke, the housing body comprising an inlet and an outlet and having an internal space defined therein, the stator back yoke being integrally embedded in the housing body; and
an impeller disposed in the internal space in the housing body and mounted to be rotatable about a rotation shaft, the impeller comprising an impeller body and a magnet.

2. The electric water pump as claimed in claim 1, wherein the PCB is integrally embedded in the housing body together with the stator back yoke.

3. The electric water pump as claimed in claim 1, wherein the PCB is structured such that a copper foil pattern, serving as a stator coil, is printed on a substrate to be integrally formed with the substrate.

4. The electric water pump as claimed in claim 1, wherein the magnet is integrally embedded in the impeller body.

5. The electric water pump as claimed in claim 1, wherein the PCB and the magnet are disposed on one surface of the housing and one surface of the impeller, respectively, facing each other in a direction parallel to the rotation shaft, and
wherein the stator back yoke is disposed opposite the magnet with respect to the PCB.

6. The electric water pump as claimed in claim 5, wherein the PCB is integrally embedded in the housing body together with the stator back yoke.

7. The electric water pump as claimed in claim 6, wherein a gap is defined between the one surface of the housing and the one surface of the impeller to allow coolant to pass between the one surface of the housing and the one surface of the impeller.

8. The electric water pump as claimed in claim 5, wherein the PCB is disposed outside the housing body on a side of the one surface of the housing.

9. The electric water pump as claimed in claim 8, wherein a gap is defined between the PCB and the one surface of the impeller to allow coolant to pass between the PCB and the one surface of the impeller.

10. The electric water pump as claimed in claim 8, wherein the impeller body comprises a rotation-shaft support portion surrounding the rotation shaft, and
wherein the PCB is formed in a ring shape to allow the rotation-shaft support portion to be located at a center of the PCB.

11. The electric water pump as claimed in claim 10, wherein a gap is defined between the PCB and the rotation-shaft support portion to allow coolant to pass between the PCB and the rotation-shaft support portion.

12. The electric water pump as claimed in claim 9, wherein a gap is defined between the PCB and the housing body to allow coolant to pass between the PCB and the housing body on a side of the one surface of the housing.

13. The electric water pump as claimed in claim 12, wherein the PCB comprises a through-hole formed therein to allow coolant to pass through the PCB.

14. The electric water pump as claimed in claim 8, wherein the housing further comprises a sealing member disposed between an edge portion of the PCB and the housing body.

15. The electric water pump as claimed in claim 1, wherein the impeller further comprises a rotor back yoke.

16. The electric water pump as claimed in claim 15, wherein the rotor back yoke is integrally embedded in the impeller body.

17. The electric water pump as claimed in claim 15, wherein the magnet and the rotor back yoke are integrally embedded in the impeller body.

18. The electric water pump as claimed in claim 15, wherein the PCB and the magnet are disposed on one surface of the housing and one surface of the impeller, respectively, facing each other in a direction parallel to the rotation shaft,
wherein the stator back yoke is disposed opposite the magnet with respect to the PCB, and
wherein the rotor back yoke is disposed opposite the PCB with respect to the magnet.

19. The electric water pump as claimed in claim 1, wherein the impeller body comprises a rotation-shaft support portion surrounding the rotation shaft, and
wherein the magnet is formed in a ring shape to allow the rotation-shaft support portion to be located at a center of the magnet.

20. The electric water pump as claimed in claim 1, wherein the impeller body comprises a rotation-shaft support portion surrounding the rotation shaft; and
wherein the electric water pump comprises a bearing disposed between the rotation-shaft support portion and the rotation shaft.
